(19) United States
(12) Patent Application Publication
(10) Pub. No.: US 2010/0163944 A1
(43) Pub. Date: Jul. 1, 2010

(54) SEMICONDUCTOR MEMORY DEVICE AND MANUFACTURING METHOD THEREFOR

(75) Inventor: Hiroyuki KANAYA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/648,244

(22) Filed: Dec. 28, 2009

(30) Foreign Application Priority Data
Dec. 26, 2008 (JP) 2008-334061

(51) Int. Cl. H01L 27/108; H01L 21/8242

(52) U.S. Cl. 257/295; 438/3; 257/E27.084; 257/E21.646

(57) ABSTRACT

A semiconductor memory device includes a switching transistor provided on a semiconductor substrate; an interlayer dielectric film on the switching transistor; a contact plug in the interlayer dielectric film; a ferroelectric capacitor above the contact plug and the interlayer dielectric film, the ferroelectric capacitor comprising a lower electrode, a ferroelectric film and an upper electrode; a diffusion layer in the semiconductor substrate, the diffusion layer electrically connecting the contact plug to the switching transistor; a hydrogen barrier film on a side surface of the ferroelectric capacitor; and an interconnection comprising a TiN film or a TiAlₓN_{y} film entirely covering up an upper surface of the upper electrode and contacting with the upper surface of the upper electrode.

### CROSS-REFERENCE TO RELATED APPLICATION

This application is based upon and claims the benefit of priority from the prior Japanese Patent Application No. 2008-334061, filed on Dec. 26, 2008, the entire contents of which are incorporated herein by reference.

### BACKGROUND OF THE INVENTION

1. Field of the Invention

The present invention relates to semiconductor memory device and manufacturing method therefore.

2. Related Art

In recent years, a ferroelectric memory device has been increasingly made larger in capacity and downscaled in size. For further downscaling of a ferroelectric capacitor, it is necessary to make a taper angle of a side surface of a ferroelectric capacitor as close to a right angle with respect to a surface of a substrate as possible. It is also necessary to provide a high-density ferroelectric film to improve characteristics of the ferroelectric capacitor.

If the taper angle of the side surface of the ferroelectric capacitor exceeds 72 degrees with respect to the surface of the substrate, a side residue (so-called “fence”) tends to be formed on a side surface of an upper electrode. The fence of this type induces leakage in the ferroelectric capacitor and causes deterioration in yield. Further, this fence reduces coverage of a hydrogen barrier film and deteriorates the characteristics of the ferroelectric capacitor.

As described in Patent Document 1, there is known a fence suppression method including forming a thin hard mask and retreating an upper edge of an upper electrode by etching. With this method, however, if a memory device is downscaled, a ferroelectric capacitor has disadvantageously irregularities in cell size. If the ferroelectric capacitor has irregularities in cell size, a signal difference (potential difference) between “0” and “1” is made small. This results in deterioration in yield.

It is preferable to deposit a ferroelectric material using CVD (Chemical Vapor Deposition) so as to form a high-density ferroelectric film. Generally, however, irregularities tend to be generated on a surface of the ferroelectric film formed by the CVD. These irregularities also appear on a surface of an upper electrode and reduce coverage of a hydrogen barrier film covering up the upper electrode. If the hydrogen barrier film has poor coverage, hydrogen produced during formation of tungsten plugs diffuses into the ferroelectric capacitor and deteriorates the ferroelectric capacitor. Moreover, the irregularities on the surface of the upper electrode cause generation of the fence.

### SUMMARY OF THE INVENTION

A semiconductor memory device according to an embodiment of the present invention comprises: a switching transistor provided on a semiconductor substrate; an interlayer dielectric film on the switching transistor; a contact plug in the interlayer dielectric film; a ferroelectric capacitor above the contact plug and the interlayer dielectric film, the ferroelectric capacitor comprising a lower electrode, a ferroelectric film and an upper electrode; a diffusion layer in the semiconductor substrate, the diffusion layer electrically connecting the contact plug to the switching transistor; a hydrogen barrier film on a side surface of the ferroelectric capacitor; and an interconnection comprising a TiN film or a TiAlₓN_{y} film entirely covering up an upper surface of the upper electrode and contacting with the upper surface of the upper electrode.

A semiconductor memory device according to an embodiment of the present invention comprises: a switching transistor provided on a semiconductor substrate; a first interlayer dielectric film on the switching transistor; a contact plug in the first interlayer dielectric film; a ferroelectric capacitor above the contact plug and the first interlayer dielectric film, the ferroelectric capacitor comprising a lower electrode, a ferroelectric film and an upper electrode; a diffusion layer in the semiconductor substrate, the diffusion layer electrically connecting the contact plug to the switching transistor; a first hydrogen barrier film on a side surface of the ferroelectric capacitor; a second hydrogen barrier film on the upper electrode, the second hydrogen barrier film being separately provided from the first hydrogen barrier film; a metal plug penetrating the second hydrogen barrier film and contacting the upper electrode; and an interconnection on the metal plug.

A method of manufacturing a semiconductor memory device according to an embodiment of the present invention comprises: forming a transistor on a semiconductor substrate; forming a contact plug connected to either a source or a drain of the transistor; forming a ferroelectric capacitor above the contact plug, the ferroelectric capacitor comprising a lower electrode, a ferroelectric film, and an upper electrode; forming a hydrogen barrier film on a side surface of the ferroelectric capacitor; polishing a residue formed on a side surface of the upper electrode during formation of the ferroelectric capacitor simultaneously with polishing of an upper surface of the upper electrode; and forming a local interconnection on the upper surface of the upper electrode.

A method of manufacturing a semiconductor memory device according to an embodiment of the present invention comprises: forming a transistor on a semiconductor substrate; forming a contact plug connected to either a source or a drain of the transistor; forming a ferroelectric capacitor above the contact plug, the ferroelectric capacitor comprising a lower electrode, a ferroelectric film, and an upper electrode; forming a first hydrogen barrier film on a side surface of the ferroelectric capacitor; polishing a residue formed on a side surface of the upper electrode during formation of the ferroelectric capacitor simultaneously with polishing of an upper surface of the upper electrode; forming a second hydrogen barrier film on a top surface of the upper electrode; forming a interlayer dielectric film on the second hydrogen barrier film; forming a metal plug penetrating the second hydrogen barrier film and the interlayer dielectric film and contacting the upper electrode; and forming a local interconnection on the metal plug.

### BRIEF DESCRIPTION OF THE DRAWINGS

FIG. 1 is a schematic cross-sectional view showing a configuration of a ferroelectric memory device according to a first embodiment of the present invention;

FIG. 2A is a cross-sectional view showing a configuration of a memory region of the ferroelectric memory device shown in FIG. 1;

FIG. 2B is a cross-sectional view showing a part of a peripheral circuit region of the ferroelectric memory device shown in FIG. 1;

FIGS. 3 to 6 are cross-sectional views showing the method of manufacturing the ferroelectric memory device according to the first embodiment;

FIG. 7 is a graph showing the relationship between a taper angle θ of the side surface of the ferroelectric capacitor FC and a height h of the fence 90;

FIG. 8 is a cross-sectional view showing a configuration of a ferroelectric memory device according to a second embodiment of the present invention;

FIGS. 9 to 12 are cross-sectional views showing a method of manufacturing the ferroelectric memory device according to the second embodiment; and

FIG. 13 is a cross-sectional view showing a configuration of a ferroelectric memory device according to a third embodiment of the present invention.

### DETAILED DESCRIPTION OF THE INVENTION

Embodiments of the present invention will be explained below in detail with reference to the accompanying drawings. Note that the invention is not limited thereto.

### First Embodiment

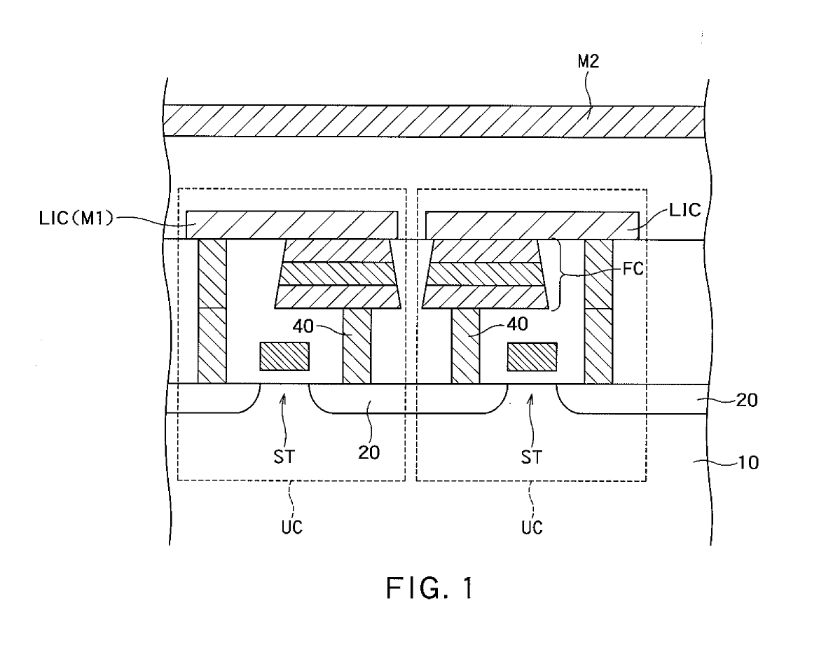

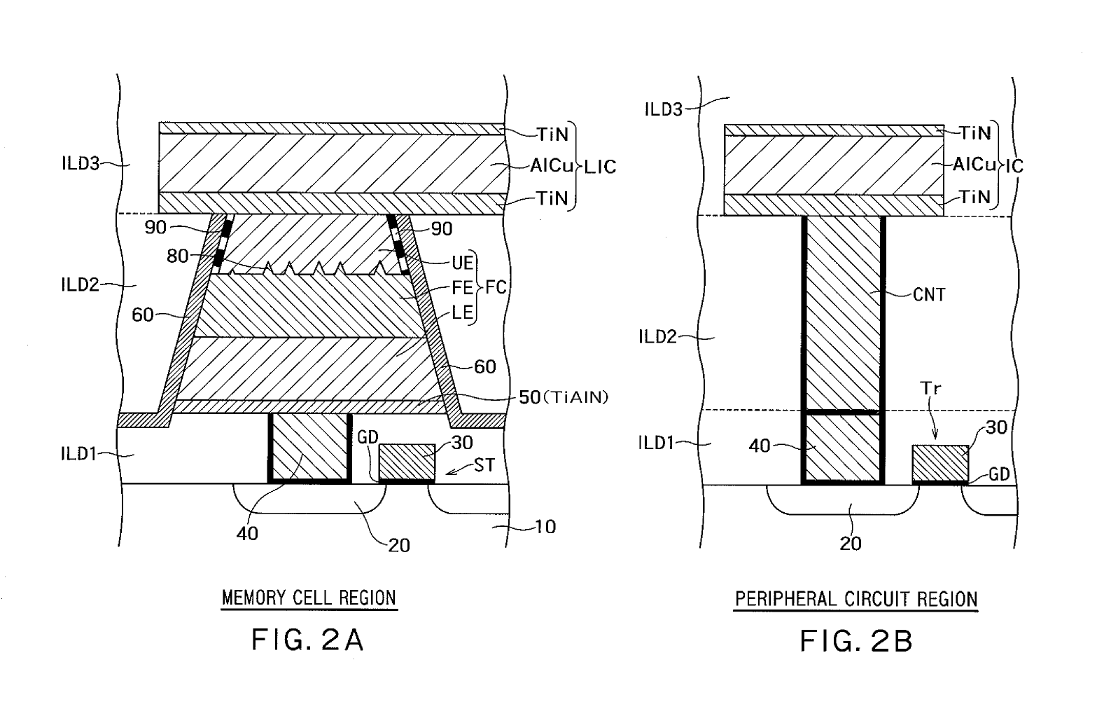

FIG. 1 is a schematic cross-sectional view showing a configuration of a ferroelectric memory device according to a first embodiment of the present invention. FIG. 2A is a cross-sectional view showing a configuration of a memory region of the ferroelectric memory device shown in FIG. 1 in more detail. FIG. 2B is a cross-sectional view showing a part of a peripheral circuit region of the ferroelectric memory device shown in FIG. 1.

As the ferroelectric memory device according to the first embodiment may be a “Series connected TC unit type ferroelectric RAM” which is a memory consisting of series connected memory cells each having a transistor having a source terminal and a drain terminal and a ferroelectric capacitor inbetween said two terminals.

As shown in FIG. 1, the Series connected TC unit type ferroelectric RAM is a ferroelectric memory device configured so that a plurality of unit cells UC is connected in series. Both ends of each ferroelectric capacitor FC are connected to between a source and a drain of one switching transistor ST, respectively. The ferroelectric capacitor FC and the switching transistor ST having the source and the drain connected to the both ends of the ferroelectric capacitor FC, respectively are referred to as “a unit cell UC”.

Furthermore, the ferroelectric memory device according to the first embodiment has a COP (Capacitor On Plug) structure. The COP structure is a structure in which each ferroelectric capacitor FC is provided right on a contact plug 40 connected to a diffusion layer 20 of the switching transistor ST. The COP structure is suited for downscaling of memories.

Needless to say, the present invention is not limited to the Series connected TC unit type ferroelectric RAM but applicable to other ferroelectric memory devices.

As shown in FIG. 2A, the ferroelectric memory device according to the first embodiment includes a silicon (Si) substrate 10 and switching transistors ST provided on the Si substrate 10. For brevity, FIG. 2A shows only one switching transistor ST. Each switching transistor ST includes a gate dielectric film GD provided on a channel region between a source and a drain of the switching transistor ST, and a gate electrode 30 provided on the gate dielectric film GD. The switching transistor ST is covered with an interlayer dielectric film ILD1. The contact plug 40 that is the tungsten plug in this embodiment penetrates through the interlayer dielectric film ILD1 and is connected to the source or drain (the diffusion layer 20) of the switching transistor ST.

A hydrogen barrier film 50 is provided on the tungsten plug 40 and the interlayer dielectric film ILD1. The hydrogen barrier film 50 is made of, for example, TiAlₓN_{y}. Each ferroelectric capacitor FC is provided on the hydrogen barrier film 50. The ferroelectric capacitor FC includes an upper electrode UE, a ferroelectric film FE and a lower electrode LE. The ferroelectric film FE is made of, for example, PZT (Pb(ZrₓTi₍₁₋ₓ₎)O₃), SBT (SrBi₂Ta₂O₉), or BLT ((Bi, La)₄Ti₃O₁₂). Symbols x, y, z, and a are positive numbers. The upper electrode UE is made of, for example, iridium oxide. The lower electrode LE is made of, for example, iridium. The ferroelectric capacitor FC and the hydrogen barrier film 60 are covered with an interlayer dielectric film ILD2.

As shown in FIG. 2A, the ferroelectric film FE has protrusions 80 provided on an upper surface of the ferroelectric film FE. If the ferroelectric film FE made of PZT or the like is deposited by the CVD, the ferroelectric film FE has a good film quality but the upper surface of the ferroelectric film FE has irregularities, that is, the protrusions 80 as shown in FIG. 2A. A height of each protrusion 80 is equal to or larger than 20 nanometers (nm). On the other hand, an upper surface of the upper electrode UE is flatter than that of the ferroelectric film FE. In other words, even if protrusions are present on the upper surface of the upper electrode UE, a height of each protrusion is smaller than 20 nm. It is known that a sidewall residue (so-called “fence”) is formed on a side surface of the upper electrode UE if the height of each protrusion on the upper surface of the upper electrode UE is equal to or larger than 20 nm. Therefore, by making the upper surface of the upper electrode UE flat, it is possible to suppress formation of the fence on the side surface of the upper electrode UE.

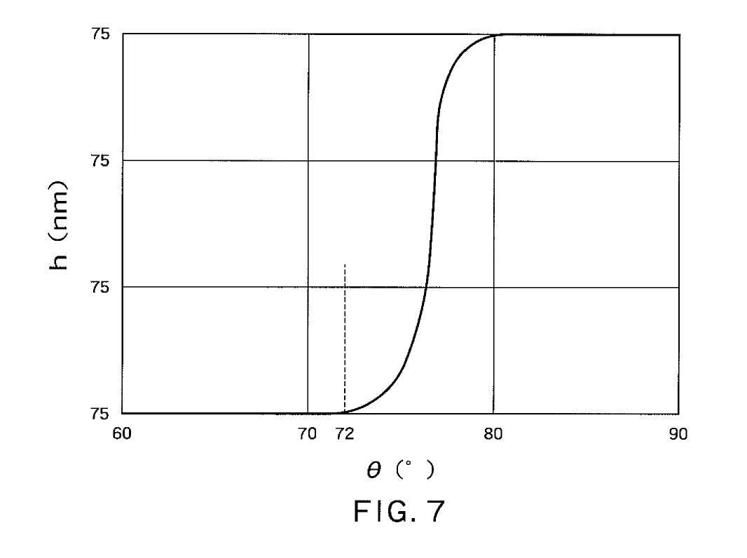

Moreover, a taper angle of a side surface of the ferroelectric capacitor FC (an angle of the side surface of the ferroelectric capacitor FC with respect to a surface of the Si substrate 10) is equal to or greater than 72 degrees. As shown in FIG. 7, if the taper angle of the side surface of the ferroelectric capacitor FC is equal to or greater than 72 degrees, a fence tends to be formed on the side surface of the upper electrode UE. On the other hand, if the taper angle of the side surface of the ferroelectric capacitor FC is closer to a right angle, this can contribute to downscaling of the ferroelectric memory device. In the first embodiment, the fence is removed by the CPU while setting the taper angle of the side surface of the ferroelectric capacitor FC to be equal to or greater than 72 degrees. Therefore, according to the first embodiment, the ferroelectric memory device can be downscaled while maintaining characteristics of the ferroelectric capacitors FC.

A side surface of each ferroelectric capacitor FC is covered with a hydrogen barrier film 60. The hydrogen barrier film 60 is not provided on the upper surface of the upper electrode UE of the ferroelectric capacitor FC. A local interconnection LIC is provided to cover up the entire upper surface of the upper electrode UE of the ferroelectric capacitor FC, and is connected to the upper surface of the upper electrode UE. The local interconnection LIC is configured to include, for example, three-layer films of a TiN film, an AlCu film, and a TiN film. An interlayer dielectric film ILD3 is provided on the local interconnection LIC.

A sidewall residue (fence) 90 remains on the side surface of the upper electrode UE. That is, the fence 90 is present between the side surface of the upper electrode UE and the hydrogen barrier film 60. However, the fence 90 does not protrude over the upper surface of the upper electrode UE. Further, the hydrogen barrier film 60 covers up outside of the fence 90. Due to this, hydrogen does not enter the ferroelectric capacitor FC. Therefore, in the first embodiment, even if the fence 90 is present, the fence 90 does not adversely influence the characteristics of the ferroelectric capacitor FC. The fence 90 is an etching residue generated when the ferroelectric capacitor FC is formed. Examples of the etching residue include iridium or the like used as a material of the upper electrode UE and iridium used as a material of the lower electrode LE. Needless to say, the fence 90 is not necessarily formed on an actual ferroelectric memory device. This is why the fence 90 is indicated by a broken line in the drawings.

As shown in FIG. 2B, transistors Tr each including the diffusion layer 20, the gate electrode 30, and the gate dielectric film GD are formed on the Si substrate 10 in a peripheral circuit region. For brevity, FIG. 2B shows only one transistor Tr. The tungsten plug 40 (hereinafter, sometimes simply “plug”) is connected to a source or a drain of the transistor Tr. Further, a contact CNT is provided on the plug 40. An interconnection IC is provided on the contact CNT and the interlayer dielectric film ILD2.

Each transistor Tr can be configured similarly to the switching transistor ST provided in the memory region. The interconnection IC can be configured similarly to the local interconnection LIC provided in the memory region. By so configuring, a method of manufacturing the ferroelectric memory device according to the first embodiment can be simplified. Although FIG. 2B shows that the peripheral circuit region has only a simple element configuration, an actual peripheral circuit region has a more complicated configuration in which many transistors Tr, many contacts CNT (as well as the plugs 40) and many interconnections IC are provided.

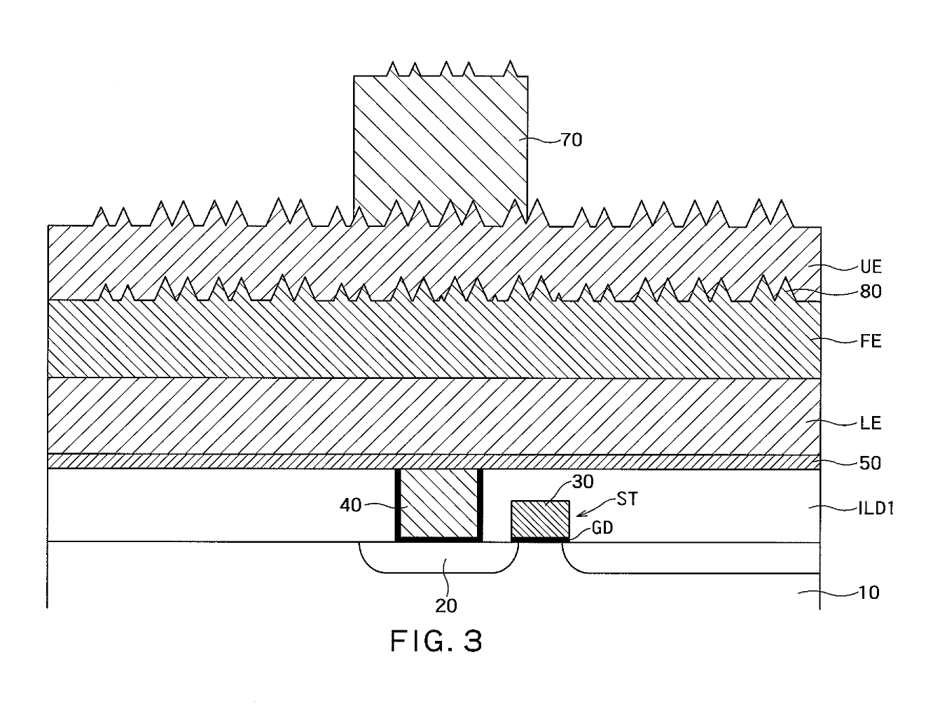

FIGS. 3 to 6 are cross-sectional views showing the method of manufacturing the ferroelectric memory device according to the first embodiment. FIGS. 3 to 6 show only the memory region and do not show the peripheral circuit region.

First, switching transistors ST are formed on the Si substrate 10 using a conventional process. Because conventional switching transistors can be used as the switching transistors ST, the switching transistors ST are not described in detail. In a process of forming each switching transistor ST, the diffusion layer 20 is formed as a source layer or a drain layer of the switching transistor ST. The interlayer dielectric film ILD1 is deposited on the switching transistor ST. The interlayer dielectric film ILD1 is, for example, a silicon oxide film or a low-k film lower in relative dielectric constant than the silicon oxide film. Contact holes reaching the diffusion layer 20 are formed and filled with metal. Thereafter, for surface flattening, the metal in the contact holes is polished up to an upper surface of the interlayer dielectric film ILD1. As a result, the plugs 40 each serving as the contact plug are formed. The plugs 40 are made of tungsten, for example.

Next, the hydrogen barrier film 50, the material of the lower electrode LE, the material of the ferroelectric film FE and the material of the upper electrode UE are deposited on the interlayer dielectric film ILD1 including each plug 40 in this order. The hydrogen barrier film 50 is a single-layer film made of, for example, titanium nitride (Ti₃N₄ or the like), titanium aluminum nitride (TiAlₓN_{y} or the like), tungsten nitride (WₓN_{y} or the like) or titanium (Ti) or a multilayer film including a combination of these single-layer films. In the first embodiment, the hydrogen barrier film 50 is the single-layer film made of TiAlₓN_{y}. A thickness of the hydrogen barrier film 50 is, for example, 30 nm.

The material of the lower electrode LE is a single-layer film made of, for example, Ir, iridium oxide (IrO₂, (hereinafter, also “IrOₓ”)), Pt, SrRuO₃, or SrRuO₃ (hereinafter, also “SRO”) or a multilayer film including a combination of these single-layer films. In the first embodiment, the material of the lower electrode LE is the single-layer film made of iridium. A thickness of the lower electrode LE is, for example, 120 nm.

The material of the ferroelectric film FE is deposited using the CVD and, for example, PZT (Pb(ZrₓTi₍₁₋ₓ₎)O₃), SBT (SrBi₂Ta₂O₉), or BLT ((Bi, La)₄Ti₃O₁₂). In the first embodiment, the material of the ferroelectric film FE is PZT. A thickness of the material of the ferroelectric film FE is, for example, 100 nm. Under normal conditions, irregularities each at a height equal to or larger than 20 nm are formed on a surface of the PZT film, that is, the ferroelectric film FE formed by the CVD.

The material of the upper electrode UE is a single-layer film made of, for example, Ir, iridium oxide (IrO₂, (hereinafter, also “IrOₓ”)), Pt, SrRuO₃, LaSrO₃, or SrRuO₃ (hereinafter, also “SRO”) or a multilayer film including a combination of these single-layer films. In the first embodiment, the material of the upper electrode UE is the multilayer film including an SRO film and an IrO₂ film. In FIGS. 3 to 6, the material of the upper electrode UE is shown as a single-layer film for brevity. A thickness of the SRO film is, for example, 10 nm. A thickness of the IrO₂ film is, for example, 90 nm.

At this stage, the protrusions 80 of the ferroelectric film FE are also transferred onto the material of the upper electrode UE. Therefore, in FIG. 3, flatness of the surface of the material of the upper electrode UE is almost equal to that of the surface of the ferroelectric film FE.

In the peripheral circuit region, after elements such as the transistors Tr are formed on the Si substrate 10, steps up to a step of forming the material of the upper electrode UE are similar to those in the memory region.

As shown in FIG. 3, a hard mask 70 is formed on the material of the upper electrode UE. The hard mask 70 is processed into a pattern of the upper electrode UE. The hard mask 70 is a multilayer film including an SiO₂ film having a thickness of 550 nm and an Al₂O₃ film having a thickness of 130 nm. The Al₂O₃ film is provided to protect the ferroelectric capacitor FC from hydrogen produced when the SiO₂ film is formed by, for example, plasma TEOS (tetraethoxysilane) method. The hard mask 70 is a single-layer film made of SiOₓ (such as SiO₂), AlₓO_{y} (such as Al₂O₃), SiAlₓO_{y} (such as SiAlO), ZrOₓ (such as ZrO₂), SiₓN_{y} (such as Si₃N₄), or TiAlₓN_{y} (such as TiAl_{0.5}N_{0.5}) or a multilayer film including a combination of these single-layer films.

In the peripheral circuit region, the hard mask 70 is entirely removed. By doing so, in a next step of processing the ferroelectric capacitor FC, the upper electrode UE, the ferroelectric film FE, the lower electrode LE, and the hydrogen barrier film 50 are all removed in the peripheral circuit region.

Using the hard mask 70 as a mask, the material of the upper electrode UE, the ferroelectric film FE, and the material of the lower electrode LE are etched by high temperature RIE (Reactive Ion Etching). A temperature of the RIE is over 250° C., for example, about 350° C. By doing so, the upper electrode UE, the ferroelectric film FE, and the lower electrode LE are processed into a pattern of each ferroelectric capacitor FC. When the material of the lower electrode LE is etched, Ir that is the material of the lower electrode LE adheres onto a side surface of the hard mask 70 and the side surface of the upper electrode UE. The sidewall residue mainly containing Ir, therefore, remains on the side surface of the upper electrode UE as the fence 90.

FIG. 7 is a graph showing the relationship between a taper angle θ of the side surface of the ferroelectric capacitor FC and a height h of the fence 90. With reference to FIG. 7, the relationship between the taper angle θ of the side surface of the ferroelectric capacitor FC and the height h of the fence 90 is described. The height h of the fence 90 indicates a height from the upper surface of the upper electrode UE (a bottom of each protrusion 80). The hard mask 70 is the multilayer film including the SiO₂ film having the thickness of 550 nm and the Al₂O₃ film having the thickness of 130 nm. The upper electrode UE is the IrO₂ film having the thickness of 90 nm. The ferroelectric film FE is the PZT film having the thickness of 100 nm. The lower electrode LE is the Ir film having the thickness of 120 nm. The hydrogen barrier film 50 is the TiAlₓN_{y} film having the thickness of 30 nm. The RIE is performed in an atmosphere at the temperature equal to or higher than 350° C. By changing the temperature of the RIE, the taper angle θ can be adjusted. If the temperature of the RIE is 350° C., the taper angle θ is equal to or greater than about 72 degrees. As obvious from the graph of FIG. 7, if the taper angle θ exceeds about 72 degrees, the height h of the fence 90 is made conspicuously large. That is, according to the conventional technique, if the taper angle θ of the side surface of the ferroelectric capacitor FC exceeds about 72 degrees, there is probability that leakage current flowing in the ferroelectric capacitor FC increases.

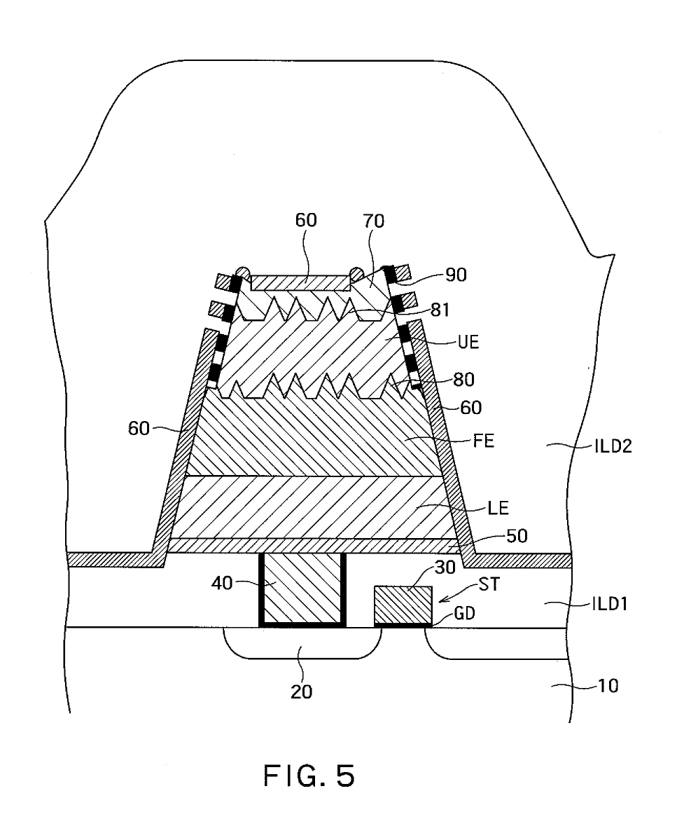

Referring back to FIG. 5, the method of manufacturing the ferroelectric memory device according to the first embodiment is described.

After forming each ferroelectric capacitor FC, the hydrogen barrier film 60 is deposited. The hydrogen barrier film 60 is a single-layer film made of SiOₓ (such as SiO₂), AlₓO_{y} (such as Al₂O₃), SiAlₓO_{y} (such as SiAlO), ZrOₓ (such as ZrO₂), or SiₓN_{y} (such as Si₃N₄) or a multilayer film including a combination of these single-layer films.

The interlayer dielectric film ILD2 is deposited on the hydrogen barrier film 60.

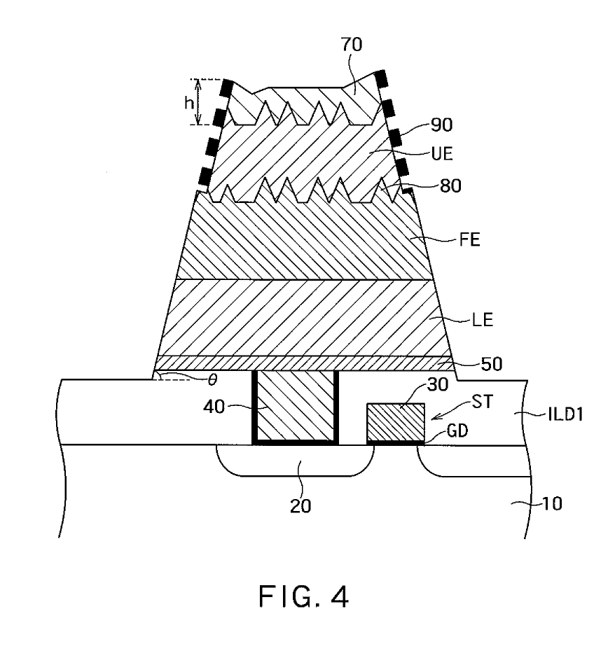

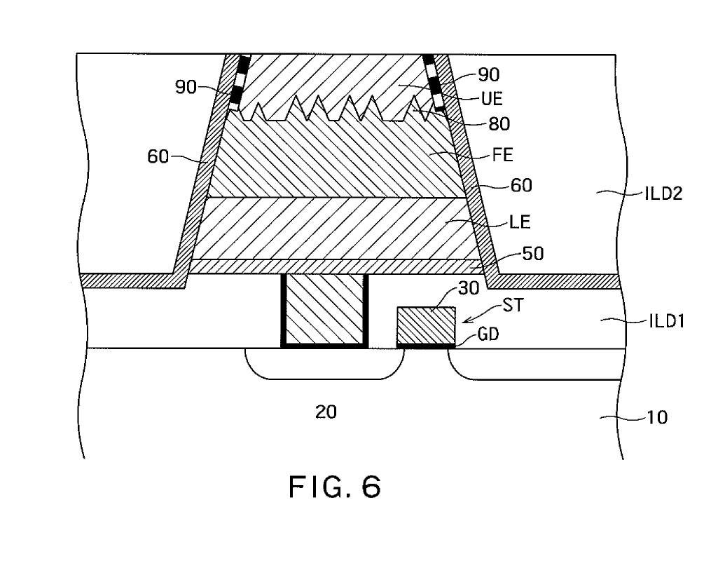

As shown in FIG. 6, the interlayer dielectric film ILD2, the upper electrode UE, the hydrogen barrier film 60, and the fence 90 are polished by CMP. At this time, the upper electrode UE is polished until the protrusions 81 present on the upper surface of the upper electrode UE are eliminated and the upper electrode UE is flattened. At the same time, the hydrogen barrier film 60 and the fence 90 are polished up to the same height level as that of the flattened upper surface of the upper electrode UE. In this way, the fence 90 is polished together with the protrusions 80 of the upper electrode UE. Due to this, no problems occur even if the fence 90 is formed to be high at the stage shown in FIG. 4. That is, in the ferroelectric memory device according to the first embodiment, the taper angle θ of the side surface of each ferroelectric capacitor FC can be set to 72 degrees to 90 degrees. By so setting, the ferroelectric memory device can be further downscaled.

Moreover, because the upper surface of the upper electrode UE is flattened by the CMP, edges of an upper portion of the upper electrode UE are not rounded but can be kept angular. This can make the ferroelectric capacitors FC uniform in size. If the ferroelectric capacitors FC are made uniform in size, a fluctuation in signal amount between “1” and “0” is made small.

In the peripheral circuit region, each contact CNT shown in FIG. 2 is formed after polishing the interlayer dielectric film ILD2.

Next, as shown in FIG. 2, a material of the local interconnection LIC is directly deposited on the upper electrode UE. The material of the local interconnection LIC is, for example, the three-layer films of the TiN film, the AlCu film, and the TiN film or three-layer films of a TiAlₓN_{y} film, AlCu film, and a TiAlₓN_{y} film. By processing the material of the local interconnection LIC by the RIE, the local interconnection LIC is formed. It is to be noted that the local interconnection LIC covers up the entire upper surface of the upper electrode UE after processing.

Although the hydrogen barrier film 60 is not provided on the upper surface of the upper electrode UE, the TiN film, or the TiAlₓN_{y} film in the local interconnection LIC can block hydrogen. Therefore, it is possible to keep the characteristics of the ferroelectric capacitor FC good by causing the local interconnection LIC to cover up the entire upper surface of the upper electrode UE.

In the peripheral circuit region, the interconnection IC is formed on the interlayer dielectric film ILD2 simultaneously with formation of the local interconnection LIC.

Thereafter, the interlayer dielectric film ILD3 shown in FIG. 2A is formed on the local interconnection LIC and the interlayer dielectric film ILD2, and a metal interconnection M2 that is a second interconnection layer is formed on the interlayer dielectric film ILD3. As a result, the ferroelectric memory device according to the first embodiment is completed.

According to the first embodiment, the protrusions 81 on the upper electrode UE and the fence 90 are polished together with the upper electrode UE by the CMP. By doing so, the upper surface of the upper electrode UE is flattened and the fence 90 is ground or polished up to the same level as that of the upper surface of the upper electrode UE. Therefore, the taper angle θ of the side surface of each ferroelectric capacitor FC can be set as sharp as 72 degrees or greater, thereby making it possible to downscale the ferroelectric capacitor FC.

Moreover, the ferroelectric film FE has the high film quality because of formation by the CVD but the protrusions 80 are present on the upper surface of the ferroelectric film FE. However, the irregularities on the upper surface of the ferroelectric film FE are negligible because the upper surface of the upper electrode UE is flattened.

Meanwhile, because the upper surface of the upper electrode UE is polished by the CMP, the hydrogen barrier film 60 cannot be left on the upper electrode UE. However, the local interconnection LIC including the TiN film or the TiAlₓN_{y} film that blocks hydrogen covers up the entire upper surface of the upper electrode UE. Therefore, each ferroelectric capacitor FC can be protected from hydrogen.

### Second Embodiment

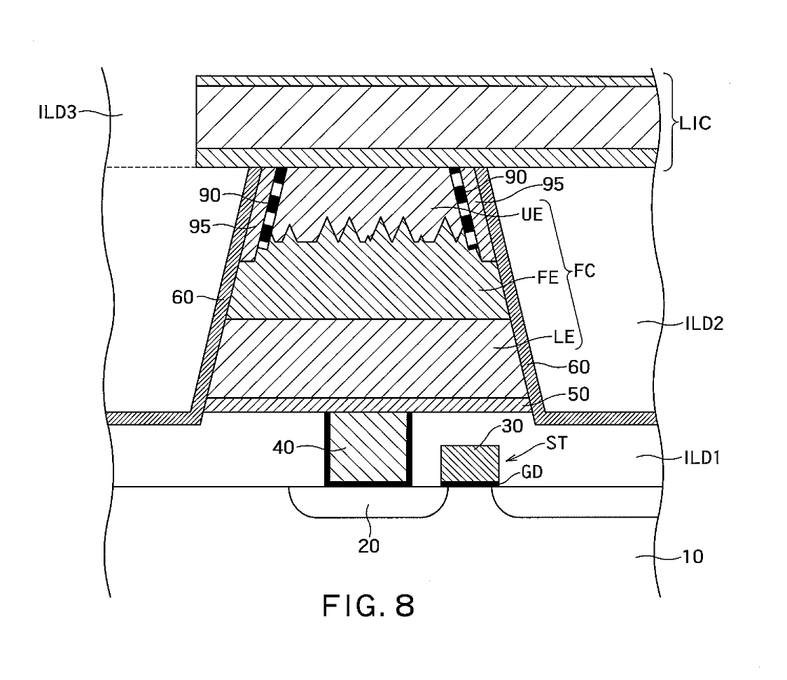

FIG. 8 is a cross-sectional view showing a configuration of a ferroelectric memory device according to a second embodiment of the present invention. In the second embodiment, not only a fence 90 and a hydrogen barrier film 60 but also a hard mask 95 remains on a part of a side surface of an upper electrode UE and a side surface of a ferroelectric film FE. The hard mask 95 is formed between the fence 90 and the hydrogen barrier 60. That is, the hard mask 95 is formed on the side surface of the upper electrode UE via the fence 90. The hydrogen barrier film 60 is formed on the side surface of the upper electrode UE via the fence 90 and the hard mask 95. Further, height-different steps are formed on portions of the side surface of the ferroelectric film FE in which portions the hard mask 95 remains. Other configurations of the second embodiment are the same as the corresponding configurations of the first embodiment.

Because a peripheral circuit region of the second embodiment is the same as that of the first embodiment, illustrations thereof will be omitted.

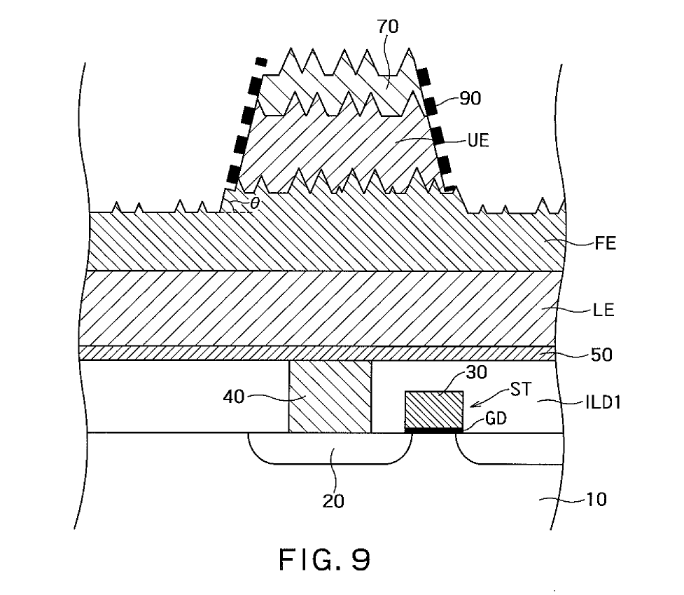

FIGS. 9 to 12 are cross-sectional views showing a method of manufacturing the ferroelectric memory device according to the second embodiment. The manufacturing method according to the second embodiment up to a step of forming the hard mask 70 shown in FIG. 3 can be executed similarly to the manufacturing method according to the first embodiment. In the second embodiment, the hard mask 70 is referred to as “first hard mask 70” for the sake of convenience. A material and a size of the first hard mask 70 can be set similarly to those of the hard mask 70 according to the first embodiment.

As shown in FIG. 9, using the first hard mask 70 as a mask, a material of the upper electrode UE and the ferroelectric film FE are etched by high temperature RIE. A temperature of the RIE is, for example, about 350° C. A taper angle θ of the side surface of each of the upper electrode UE and the ferroelectric film FE is set as sharp as degrees or greater. The RIE is stopped halfway along the ferroelectric film FE.

At this time, a material of a lower electrode LE is not etched yet. However, because of the sharp taper angle θ, an etching residue of the upper electrode UE and the ferroelectric film FE is formed on the side surface of the upper electrode UE and a side surface of the first hard mask 70 as the fence 90.

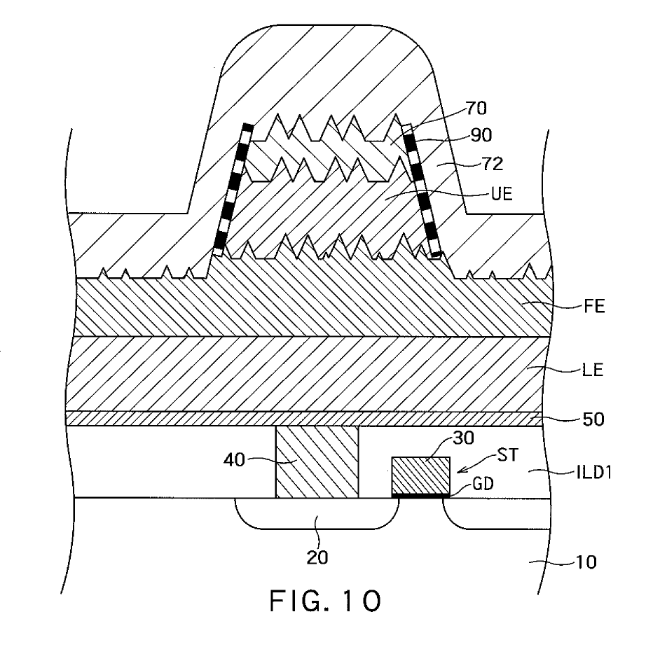

As shown in FIG. 10, a material of a second hard mask 72 is deposited on the fence 90, the ferroelectric film FE, and the first hard mask 70. The material of the second hard mask 72, which is similar to that of the first hard mask 70, is a single-layer film made of SiOₓ (such as SiO₂), AlₓO_{y} (such as Al₂O₃), SiAlₓO_{y} (such as SiAlO), ZrOₓ (such as ZrO₂), SiₓN_{y} (such as Si₃N₄), or TiAlₓN_{y} (such as TiAl_{0.5}N_{0.5}) or a multilayer film including a combination of these single-layer films.

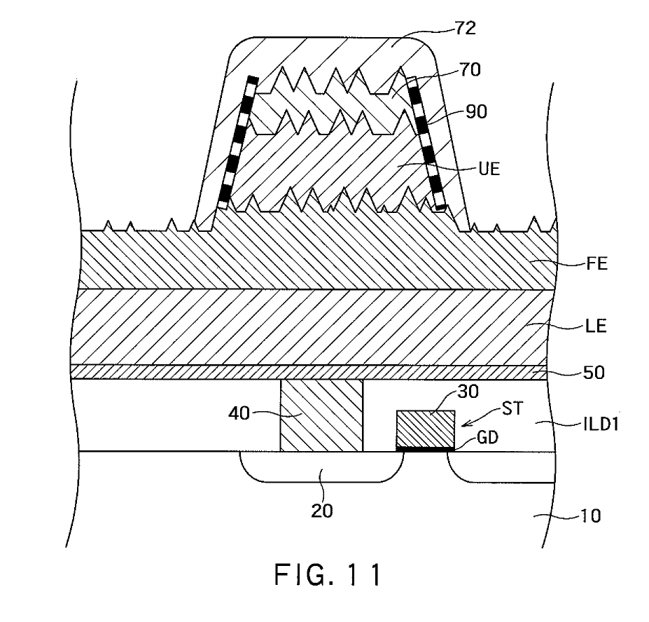

Next, as shown in FIG. 11, the second hard mask 72 is etched back by the RIE. By doing so, the second hard mask 72 is left on the fence 90 (the side surface of the upper electrode UE and the side surface of the first hard mask 70). The second hard mask 72 can be also left on an upper surface of the first hard mask 70.

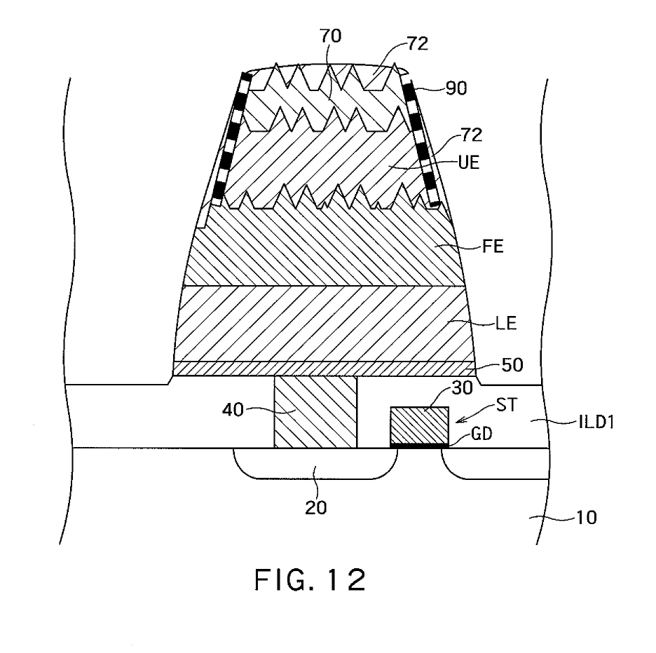

Next, as shown in FIG. 12, using the second hard mask 72 (and the first hard mask 70) as a mask, a lower portion of the ferroelectric film FE and the lower electrode LE are etched by the high temperature RIE. A temperature of the RIE is, for example, about 350° C. By doing so, the upper electrode UE, the ferroelectric film FE, and the lower electrode LE are processed into a pattern of each ferroelectric capacitor FC. When the material of the lower electrode LE is etched, Ir that is the material of the lower electrode LE adheres onto a side surface of the second hard mask 70. However, because of the presence of the second hard mask 72 and the fence 90, iridium from the lower electrode LE does not directly adhere onto the side surface of the upper electrode UE. Therefore, the second embodiment can further suppress the risk of leakage current in the ferroelectric capacitor FC. The taper angle θ of the side surface of each ferroelectric capacitor FC is as sharp as 72 degrees or greater. The second embodiment can thereby achieve the same effects as those of the first embodiment.

Thereafter, a step of forming the hydrogen barrier film 60 and subsequent steps of manufacturing the ferroelectric memory according to the second embodiment are the same as those according to the first embodiment described above with reference to FIGS. 1, 2, 5, and 6. As a result, the ferroelectric memory device according to the second embodiment is completed.

The second embodiment can achieve not only the effects described above but also the same effects as those of the first embodiment.

### Third Embodiment

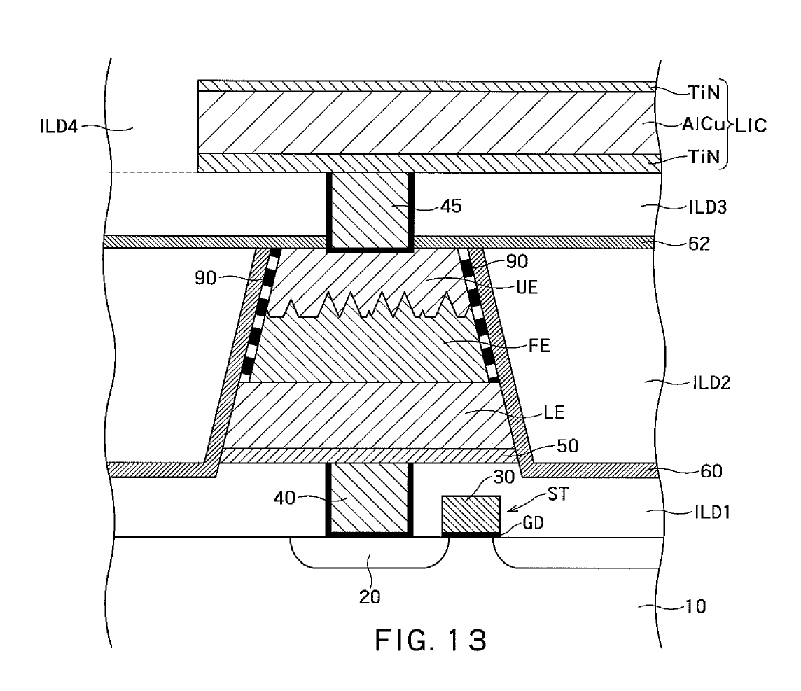

FIG. 13 is a cross-sectional view showing a configuration of a ferroelectric memory device according to a third embodiment of the present invention. The ferroelectric memory device according to the third embodiment includes a second hydrogen barrier film 62 different from a first hydrogen barrier film 60 and contact plugs 45 each connecting an upper electrode UE to a local interconnection LIC. Other configurations of the third embodiment are the same as the corresponding configurations of the first embodiment. The configuration of the first hydrogen barrier film 60 of the third embodiment can be the same as that of the first embodiment.

A method of manufacturing the ferroelectric memory device according to the third embodiment is described below. As shown in FIG. 13, the second hydrogen barrier film 62 is formed on a flattened interlayer dielectric film ILD2 and the upper electrode UE. A material of the second hydrogen barrier film 62 is a single-layer film made of SiOₓ (such as SiO₂), AlₓO_{y} (such as Al₂O₃), SiAlₓO_{y} (such as SiAlO), ZrOₓ (such as ZrO₂), or SiₓN_{y} (such as Si₃N₄) or a multilayer film including a combination of these single-layer films.

An interlayer dielectric film ILD3 is then deposited on the second hydrogen barrier film 62. The interlayer dielectric film ILD3 is, for example, plasma TEOS having a thickness of 200 nm. A contact hole is formed to penetrate through the interlayer dielectric film ILD3 and the second hydrogen barrier film 62 and to contact each upper electrode UE. The contact hole is filled with tungsten or aluminum, thereby forming a contact plug 45 penetrating through each second hydrogen barrier film 62 and contacting each upper electrode UE. If the contact hole is filled with tungsten by MO-CVD, hydrogen is produced. Therefore, if the contact hole is filled with tungsten, a thin NbN film or TiN film is formed in the contact hole as a hydrogen barrier film before the MO-CVD.

Thereafter, the local interconnection LIC and the like are formed similarly to the first embodiment, thereby completing the ferroelectric memory device according to the third embodiment.

In the third embodiment, the upper surface of the upper electrode UE and the upper surface of the interlayer dielectric film ILD2 are covered with the second hydrogen barrier film 62. It is thereby possible to block entry of hydrogen from the upper surface of the upper electrode UE. Further, the third embodiment can also achieve the same effects as those of the first embodiment.

The second hydrogen barrier film 62 and the contact plugs 45 according to the third embodiment can be added to the ferroelectric memory device according to the second embodiment. Effects of the second and third embodiments can be achieved at the same time by combining these embodiments.

Each of the first to third embodiments can be applied to the TC parallel unit series-connected ferroelectric memory device mentioned above.

1. A semiconductor memory device comprising:
a switching transistor provided on a semiconductor substrate;
an interlayer dielectric film on the switching transistor;
a contact plug in the interlayer dielectric film;
a ferroelectric capacitor above the contact plug and the interlayer dielectric film, the ferroelectric capacitor comprising a lower electrode, a ferroelectric film and an upper electrode;
a diffusion layer in the semiconductor substrate, the diffusion layer electrically connecting the contact plug to the switching transistor;
a hydrogen barrier film on a side surface of the ferroelectric capacitor; and
an interconnection comprising a TiN film or a TiAlₓN_{y} film entirely covering up an upper surface of the upper electrode and contacting with the upper surface of the upper electrode.

2. The device of claim 1, wherein
an angle of a side surface of the ferroelectric capacitor with respect to a surface of the semiconductor substrate is equal to or greater than 72 degrees, and
the upper surface of the upper electrode is flatter than an upper surface of the ferroelectric film.

3. The device of claim 1, further comprising a fence on a side surface of the upper electrode, the fence being made of a material of the lower electrode.

4. The device of claim 1, wherein the hydrogen barrier film is not on the upper surface of the upper electrode.

5. The device of claim 3, further comprising:
a hard mask on the side surface of the upper electrode via the fence, wherein
the hydrogen barrier film is on the side surface of the upper electrode via the fence and the hard mask.

6. The device of claim 1, wherein
a height of a protrusion on an upper surface of the ferroelectric film is equal to or larger than 20 nanometers (nm), and
a height of a protrusion on the upper surface of the upper electrode is smaller than 20 nm.

7. The device of claim 1, wherein the device is a memory which consists of series connected memory cells each having a transistor having a source terminal and a drain terminal and a ferroelectric capacitor inbetween said two terminals.

8. A semiconductor memory device comprising:
a switching transistor provided on a semiconductor substrate;
a first interlayer dielectric film on the switching transistor;
a contact plug in the first interlayer dielectric film;
a ferroelectric capacitor above the contact plug and the first interlayer dielectric film, the ferroelectric capacitor comprising a lower electrode, a ferroelectric film and an upper electrode;
a diffusion layer in the semiconductor substrate, the diffusion layer electrically connecting the contact plug to the switching transistor;
a first hydrogen barrier film on a side surface of the ferroelectric capacitor;
a second hydrogen barrier film on the upper electrode, the second hydrogen barrier film being separately provided from the first hydrogen barrier film;
a metal plug penetrating the second hydrogen barrier film and contacting the upper electrode; and
an interconnection on the metal plug.

9. The device of claim 8, wherein
the first hydrogen barrier film is also provided on the first interlayer dielectric film,
the device further comprises a second interlayer dielectric film provided on the first hydrogen barrier film, and
the second hydrogen barrier film is also provided on the second interlayer dielectric film.

10. The device of claim 8, wherein
an angle of a side surface of the ferroelectric capacitor with respect to a surface of the semiconductor substrate is equal to or greater than 72 degrees, and
the upper surface of the upper electrode is flatter than an upper surface of the ferroelectric film.

11. The device of claim 8, wherein the device is a memory which consists of series connected memory cells each having a transistor having a source terminal and a drain terminal and a ferroelectric capacitor inbetween said two terminals.

12. A method of manufacturing a semiconductor memory device, comprising:
forming a transistor on a semiconductor substrate;
forming a contact plug connected to either a source or a drain of the transistor;
forming a ferroelectric capacitor above the contact plug, the ferroelectric capacitor comprising a lower electrode, a ferroelectric film, and an upper electrode;
forming a hydrogen barrier film on a side surface of the ferroelectric capacitor;
polishing a residue formed on a side surface of the upper electrode during formation of the ferroelectric capacitor simultaneously with polishing of an upper surface of the upper electrode; and
forming a local interconnection on the upper surface of the upper electrode.

13. The method of claim 12, wherein the ferroelectric film is formed by CVD, and a protrusion is formed on an upper surface of the ferroelectric film.

14. The method of claim 12, wherein the residue formed on the upper surface of the upper electrode and the residue formed on the side surface of the upper electrode are polished by CMP.

15. The method of claim 12, wherein the forming of the ferroelectric capacitor above the contact plug comprises:
forming a first hard mask on a material of the upper electrode;
etching the upper electrode and an upper portion of the ferroelectric film using the first hard mask as a mask;
forming a second hard mask on the side surface of the upper electrode and the side surface of the ferroelectric film; and
etching a lower portion of the ferroelectric film and the lower electrode using at least the second hard mask as a mask.

16. The method of claim 12, wherein the local interconnection is formed to entirely cover up the upper surface of the upper electrode.

17. A method of manufacturing a semiconductor memory device, comprising:
forming a transistor on a semiconductor substrate;
forming a contact plug connected to either a source or a drain of the transistor;
forming a ferroelectric capacitor above the contact plug, the ferroelectric capacitor comprising a lower electrode, a ferroelectric film, and an upper electrode;
forming a first hydrogen barrier film on a side surface of the ferroelectric capacitor;
polishing a residue formed on a side surface of the upper electrode during formation of the ferroelectric capacitor simultaneously with polishing of an upper surface of the upper electrode;
forming a second hydrogen barrier film on a top surface of the upper electrode;
forming a interlayer dielectric film on the second hydrogen barrier film;
forming a metal plug penetrating the second hydrogen barrier film and the interlayer dielectric film and contacting the upper electrode; and
forming a local interconnection on the metal plug.

18. The method of claim 12, wherein the ferroelectric capacitor is etched by RIE at a temperature equal to or higher than 250° C.

19. The method of claim 17, wherein the ferroelectric capacitor is etched by RIE at a temperature equal to or higher than 250° C.
